(19) United States
(12) Patent Application Publication
(10) Pub. No.: US 2025/0068796 A1
(43) Pub. Date: Feb. 27, 2025

(54) METHOD AND DEVICE WITH SPECTRUM MODELING

(71) Applicant: SAMSUNG ELECTRONICS CO., LTD., Suwon-si (KR)

(72) Inventors: Sang Ha PARK, Suwon-si (KR); Hasup LEE, Suwon-si (KR); Kuhwan JEONG, Suwon-si (KR)

(73) Assignee: SAMSUNG ELECTRONICS CO., LTD., Suwon-si (KR)

(21) Appl. No.: 18/397,797

(22) Filed: Dec. 27, 2023

(30) Foreign Application Priority Data
Aug. 21, 2023 (KR) 10-2023-0109052

(51) Int. Cl. G06F 30/25

(52) U.S. Cl. CPC G06F 30/25

(57) ABSTRACT

A method and device with spectrum modeling are disclosed. The electronic device includes one or more processors and a memory electrically connected to the processor and storing instructions configured to cause the one or more processors to: determine, based on a spectrum and a number of clusters, initial values of respective parameters included in a resonance mixture model that models a resonance function; determine, for each of the number of clusters, values of the parameters based on a loss between the spectrum and the resonance mixture model; and generate a model corresponding to the spectrum based on the determined values of the parameters.

### CROSS-REFERENCE TO RELATED APPLICATIONS

This application claims the benefit under 35 USC § 119 (a) of Korean Patent Application No. 10-2023-0109052, filed on Aug. 21, 2023, in the Korean Intellectual Property Office, the entire disclosure of which is incorporated herein by reference for all purposes.

### BACKGROUND

### 1. Field

The following description relates to a method device with spectrum modeling.

### 2. Description of Related Art

The properties or structure of a material, for example chemical composition, may be understood by measuring and analyzing the absorption and emission spectrum (e.g., PL (Photoluminescence), EL (electroluminescence), Raman spectrum, etc.) of the material.

In noisy or low-resolution segments of a measurement spectrum, it is challenging to accurately extract features of the measurement spectrum such as peaks and areas of the spectrum, such features being used to identify traits of the measured material.

A method of denoising or preprocessing a spectrum measurement involves predicting the spectrum using the values before and after data, assuming that the shape of the spectrum is a predetermined graph distribution, and then performing modeling.

The above-mentioned information is mentioned as related art to enhance the understanding of the present disclosure. Such presentation does not imply the applicability of any of the foregoing information as prior art with respect to the subject matter of the present disclosure covered by the claims of the present disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, an electronic device includes: one or more processors; and a memory electrically connected to the processor and storing instructions configured to cause the one or more processors to: determine, based on a spectrum and a number of clusters, initial values of respective parameters included in a resonance mixture model that models a resonance function; determine, for each of the number of clusters, values of the parameters based on a loss between the spectrum and the resonance mixture model; and generate a model corresponding to the spectrum based on the determined values of the parameters.

The instructions may be further configured to cause the one or more processors to determine an optimal number of clusters based on the number of clusters and the loss.

The instructions may be further configured to cause the one or more processors to generate, based on set noise information, a denoised model in which noise information is removed from the generated model.

The instructions may be further configured to cause the one or more processors to generate separate models from the model based on the determined values of the parameters.

The instructions may be further configured to cause the one or more processors to set the initial values of the parameters for each of the number of clusters within a set maximum number of clusters.

The instructions may be further configured to cause the one or more processors to select, as the values of the parameters for the model, from among the determined values, values that correspond to when the loss is within a set range.

In another general aspect, an electronic device includes: one or more processors; and a memory electrically connected to the one or more processors and configured to cause the one or more processors to: sample a spectrum including measures of frequency or wavelength sub-bands; for a number of molecule clusters, determine, based on the spectrum, respective sets of initial values of parameters included in resonance mixture models that model a resonance function; determine, for each of the number of molecule clusters, according to the initial values and the resonance mixture models, optimal values of the parameters that minimize a loss between the sampling of the spectrum and the resonance mixture models; and generate, based on the determined optimal values of the parameters, a model corresponding to the spectrum among the resonance mixture models.

The instructions may be further configured to cause the one or more processors to determine an optimal number of clusters based on the number of clusters and the loss.

The instructions may be further configured to cause the one or more processors to generate, based on set noise information, a denoised model in which noise information is removed from the generated model.

The instructions may be further configured to cause the one or more processors to generate separate models from the model based on the determined optimal values.

In yet another general aspect, a method of modeling a spectrum is performed by a computing device and the method includes: for a number of molecule clusters, determining, based on a spectrum, respective initial values of a plurality of parameters included in a resonance mixture model that models a resonance function; determining values of the parameters based on a loss between the spectrum and values produced by the resonance mixture model for each of the number of clusters; and generating a model corresponding to the spectrum based on the determined values of the parameters.

The generating of the model may include determining an optimal number of molecule clusters based on the number of molecule clusters and the loss.

The method may further include generating, based on set noise information, a denoised model in which noise information is removed from the model.

The method may further include generating separate models from the model based on the determined values of the parameters.

The determining of the initial values of the parameters may include setting the initial values for each of the number of molecule clusters within a set maximum number of clusters.

The generating of the model may include selecting the resonance mixture model as the model when the loss is within a set range.

The resonance mixture model may model two or more resonant motion modes of atoms in a molecule, and the two or more resonant motion modes may include two or more of: a symmetric stretch mode, an asymmetric stretch mode, a bending mode, or a rocking mode.

The values may be determined for the model using an optimization algorithm that iteratively finds the values that minimize loss between the spectrum and the values produced by the resonance mixture model.

Other features and aspects will be apparent from the following detailed description, the drawings, and the claims.

### BRIEF DESCRIPTION OF THE DRAWINGS

FIG. 1 illustrates an example electronic device, according to one or more embodiments.

FIG. 2 illustrates an example of modeling vibration of a molecule, according to one or more embodiments.

FIG. 3 illustrates an example resonance function of a molecule, according to one or more embodiments.

FIG. 4 illustrates an example method of modeling a spectrum, according to one or more embodiments.

FIG. 5 illustrates an example of determining initial values of parameters of a resonance mixture model by an electronic device, according to one or more embodiments.

FIGS. 6 and 7 illustrate an example model of a spectrum, according to one or more embodiments.

FIG. 8 illustrates an example of a separate model of a model that models a spectrum, according to one or more embodiments.

FIG. 9 illustrates an example method of modeling a spectrum, according to one or more embodiments.

Throughout the drawings and the detailed description, unless otherwise described or provided, it may be understood that the same or like drawing reference numerals refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

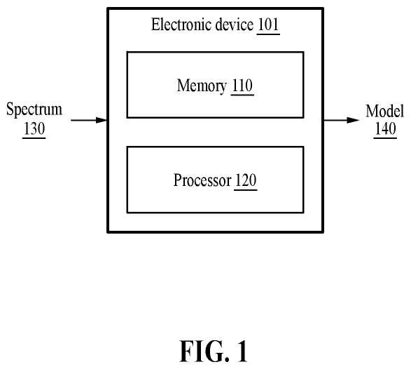

FIG. 1 illustrates an example of an electronic device 101, according to one or more embodiments.

The electronic device 101 may include a memory 110 and a processor 120.

The memory 110 may store various pieces of data and/or instructions used by at least one component (e.g., the processor 120 or a sensor module) of the electronic device 101. The various pieces of data/instructions may include, for example, software (e.g., a program in the form of executable/interpretable/compilable code) and input data or output data for a command related thereto. The memory may include a volatile memory and/or a non-volatile memory.

The processor 120 may execute, for example, software (e.g., a program in the form of code) to control at least one other component (e.g., a hardware or software component) of the electronic device 101 connected to the processor 120 and may perform various data processing or computation as described below. As at least a part of data processing or computation, the processor 120 may store a command or data received from another component (e.g., a sensor module or a communication module) in a volatile memory, process the command or the data stored in the volatile memory, and store resulting data in a non-volatile memory. The processor 120 may include a main processor (e.g., a central processing unit (CPU) or an application processor (AP)) or an auxiliary processor (e.g., a graphics processing unit (GPU), a neural processing unit (NPU), an image signal processor (ISP), a sensor hub processor, or a communication processor (CP)) that is operable independently from or in conjunction with the main processor. For example, when the electronic device 101 includes the main processor and the auxiliary processor, the auxiliary processor may be adapted to consume less power than the main processor or to be specific to a specified function. The auxiliary processor may be implemented separately from the main processor or as a part of the main processor. The description below will suffice to allow an ordinary engineer, using software/hardware development tools, to construct source code and/or circuits configured to function as described herein. Although some of the disclosure below is described in functional terms, such functional features are nonetheless features of hardware/software.

The auxiliary processor may control at least some of functions or states related to at least one (e.g., a display module, a sensor module, or a communication module) of the components of the electronic device 101, instead of the main processor while the main processor is in an inactive (e.g., sleep) state or along with the main processor while the main processor is in an active state (e.g., executing an application). The auxiliary processor (e.g., an ISP or a CP) may be implemented as a portion of another component (e.g., a camera module or a communication module) that is functionally related to the auxiliary processor.

The auxiliary processor (e.g., an NPU) may include a hardware structure configured for processing that may be particularly efficient for processing artificial intelligence (AI) models. An AI model may be generated through a machine learning algorithm. Such learning may be performed by, for example, the electronic device 101 (or another like device) in which the AI model is executed or performed via a separate server (e.g., a server). Learning algorithms may include, but are not limited to, for example, supervised learning algorithms, unsupervised learning algorithms, semi-supervised learning algorithms, or reinforcement learning algorithms. The AI model may include any of various types of neural networks which may have layers (e.g., an input layer, hidden layer(s), and output layer, etc.). A neural network may include, for example, a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or the like, or combination of two or more thereof, but is not limited thereto. The AI model may additionally or alternatively include a software structure other than the hardware structure.

For example, the electronic device 101 may model a spectrum 130 (a measurement) using a resonance mixture model based on a resonance function, as described below. The electronic device 101 may generate a model 140 that models a spectrum.

For example, the electronic device 101 may model the spectrum 130 using a resonance mixture model based on a resonance function that models the vibrational motion (e.g., underdamped oscillation) of a molecule.

The spectrum 130 (measurement) may have been measured using photoluminescence spectroscopy, infrared (IR) spectroscopy (vibrational spectroscopy), Raman spectroscopy, or the like. For example, the spectrum 130 may be measured to analyze characteristics of an element/molecule/compound. For example, the spectrum 130 may be measures of energy of respective bands (frequencies or wavelengths) of optical (electromagnetic radiation) spectrum absorbed and/or emitted according to the vibration of a molecule included in a material.

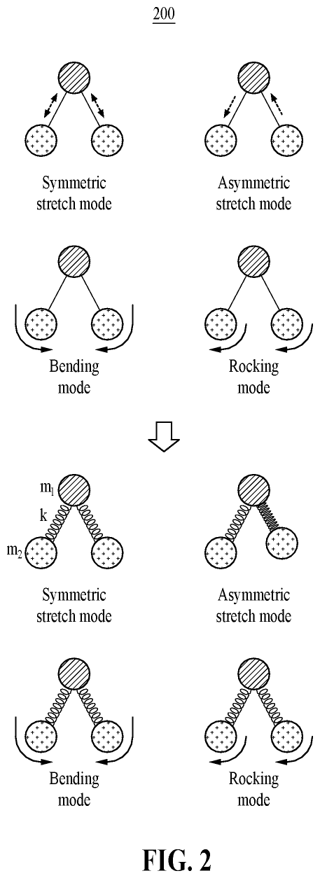

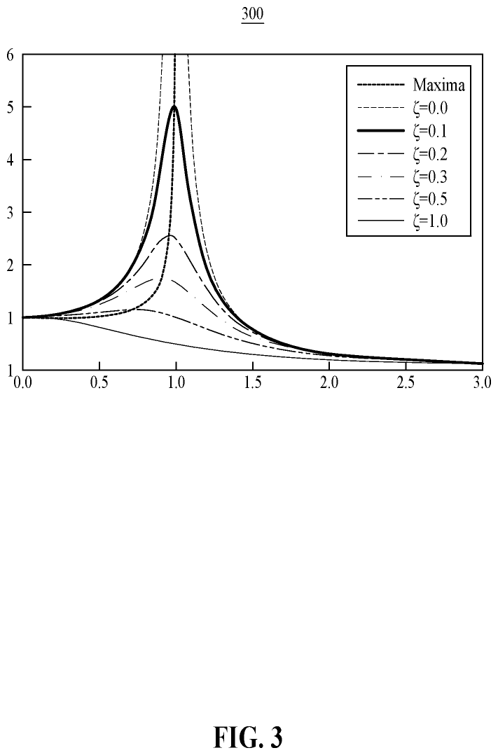

FIG. 2 illustrates an example of modeling 200 vibration of a molecule, according to one or more embodiments. FIG. 3 illustrates an example resonance function of a molecule, according to one or more embodiments.

The spectrum 130 measured using photoluminescence spectroscopy, IR spectroscopy, or Raman spectroscopy, for example, may exhibit a characteristic of widening (expanding) as the light intensity decreases, with an upward-pointed and downward-broadened shape. The spectrum 130 may have a left-right asymmetric shape. The spectrum 130 may be the result of a harmonic oscillation motion of molecules included in an element that emits light.

When a molecule, of the molecules being measured, has an electron in a ground state and a photon falls upon the molecule, the molecule absorbs the energy of the electron and in addition to the electron possibly elevating, vibration may occur due to molecular structure of the molecule. Briefly, such molecular vibration may be a periodic motion of the atoms of the molecule. The vibration may be such that the center of mass of the molecule remains largely unchanged. This vibrational motion of the atoms of the molecule may be a type of harmonic motion.

Similar to modeling of molecular vibration (e.g., a symmetric stretch mode, an asymmetric stretch mode, a bending mode, and a rocking mode) as illustrated in FIG. 2, a molecule may have various vibration modes and include a combination of multiple harmonic motions. As the size of the molecule increases, the number of vibration modes may increase in proportion to the number of atoms in the molecule. A molecular vibration may be a combination of harmonic motions according to the number of atoms in a molecule and the number of vibration modes.

The vibrational state of a molecule may be examined using photoluminescence spectroscopy, IR spectroscopy, Raman spectroscopy, or the like.

A system that moves when a molecule of mass m having damping force d and elastic force k may be referred to as “driven damped harmonic oscillation” and may be simulated using a spring-mass damper system.

$${F}_{m} + {F}_{d} + {F}_{k} = F ( t ) \qquad Equation 1$$

$$m \frac{{d}^{2} x}{{dt}^{2}} + c \frac{dx}{dt} + kx = F ( t )$$

$$x ( t ) = {Ae}^{- ζ {ω}_{0} t} cos ( \sqrt{1 - {ζ}^{2}} {ω}_{0} t + φ )$$

$$ζ = \frac{c}{2 \sqrt{mk}} ,$$

$${ω}_{0} = \sqrt{\frac{k}{m}}$$

Equation 1 above shows the solution x(t) when underdamped oscillation occurs in a molecule. In Equation 1, oscillation x(t) is at a frequency of \sqrt{1−ζ²ω₀} and may have an amplitude that decays exponentially.

As time elapses after an external force (e.g., an incident photon) is applied to the system, the system resonates at an inherent oscillation frequency. The mathematical expression for the magnitude of the transfer function of the system in this scenario may be expressed by Equation 2. The transfer function, as shown in a graph 300 of FIG. 3, may have a maximum value at the resonance frequency ω₀, with an upward-pointed and downward-broadened shape.

$$G ( ω ; {ω}_{0} , ζ ) = \frac{2 ζ {ω}_{0} ω}{\sqrt{{( 2 {ω}_{0} ω ζ )}^{2} + {( {ω}_{0}^{2} - {ω}^{2} )}^{2}}} \qquad Equation 2$$

The electronic device 101 may use a resonance mixture model based on the transfer function of the resonance system in Equation 2, or simply the resonance function, to model the spectrum 130. For example, the resonance mixture model may be represented as a combination or linear combination of resonance functions, as expressed by Equation 3.

$$G ( ω ; {α}_{1 : n} , {ω}_{1 : n} , {ζ}_{1 : n} ) = {α}_{1} {G}_{1} ( ω ; {ω}_{1} , {ζ}_{1} ) + {α}_{2} {G}_{2} ( ω ; {ω}_{2} , {ζ}_{2} ) + {α}_{3} {G}_{3} ( ω ; {ω}_{3} , {ζ}_{3} ) + ⋯ + {α}_{n} {G}_{n} ( ω ; {ω}_{n} , {ζ}_{n} ) \qquad Equation 3$$

In Equation 3, n represents the number of clusters (e.g., the number of different types of clusters of molecules), α_{1:n} represents a weight, ω_{1:n} represents an angular frequency, and ζ_{1:n} represents a damping ratio.

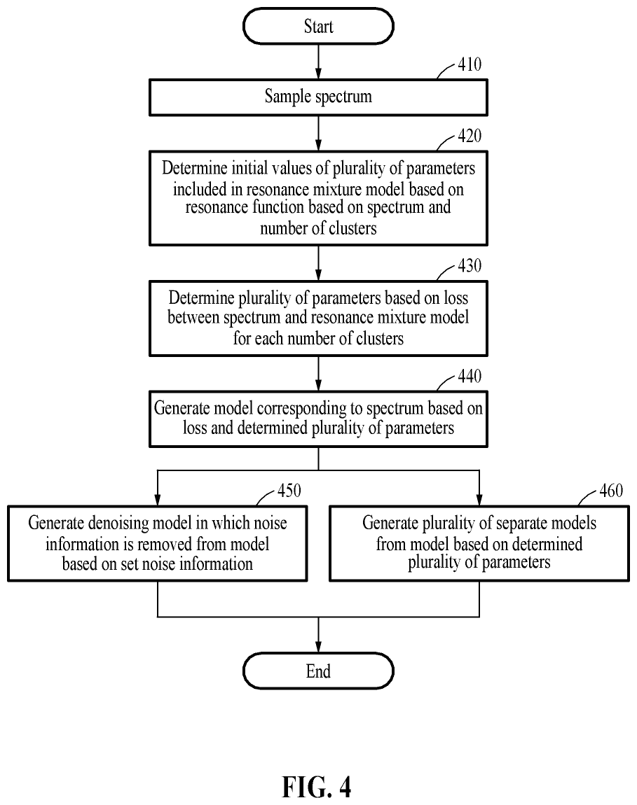

FIG. 4 illustrates an example of operations of a method of modeling a spectrum, according to one or more embodiments.

It may be understood that operations 410 to 460 are performed by the processor 120 of the electronic device 101. The operations of FIG. 4 may begin with a spectrum 130. The spectrum 130 may be intensities of spectrum sub-bands.

In operation 410, the electronic device 101 may sample the spectrum 130 (or a measurement function M(ω)). The electronic device 101 may upsample and/or resample the spectrum 130. For example, the electronic device 101 may convert the spectrum 130 as measured in the time domain into a signal in the frequency domain. For example, in operation 410, the electronic device 101 may normalize the spectrum 130.

For example, the spectrum 130 may represent an optical spectrum emitted from an element. The spectrum 130 may have been measured using photoluminescence spectroscopy, IR spectroscopy, Raman spectroscopy, or the like. However, examples are not limited to the foregoing examples, and the spectrum may be measured using various spectrum measurement techniques.

In operation 420, the electronic device 101 may determine, based on the spectrum 130 and the number of clusters, initial values of respective parameters included in a resonance mixture model based on a resonance function.

For example, the number of molecule clusters may be represented by n in Equation 3 above.

$${ω}_{n} = \{ \begin{matrix}max ( M ) , & if n = 0 \\ {ω}_{0} + \frac{( n + 1 ) * b}{2} , & if n > 1 and n is even \\ {ω}_{0} - \frac{n * b}{2} , & if n > 1 and n is odd\end{matrix} \qquad Equation 4$$

The electronic device 101 may determine, as per Equation 4 above, the initial value of the parameter ωₙ when the number of clusters is n. Alternatively, the initial value of the parameter ωₙ may be set by referencing the value of the parameter ωₙ₋₁. In operation 420, the electronic device 101 may determine the initial values of α_{1:n}, ζ_{1:n} in Equation 3 above, for example, by using the initial value of the parameter ωₙ and the spectrum 130.

In operation 430, the electronic device 101 may determine the values of the parameters based on the loss between the spectrum 130 and the resonance mixture model that is based on the number of clusters.

For example, the electronic device 101 may determine the values of the parameters that minimize a loss (e.g., L2 loss), as expressed by Equation 5 below.

$${min}_{{α}_{1 : n} , {ω}_{1 : n} , {ζ}_{1 : n}} {\sum }_{ω} {( M ( ω ) - G ( ω ; {α}_{1 : n} , {ω}_{1 : n} , {ζ}_{1 : n} ) )}^{2} \qquad Equation 5$$

The electronic device 101 may determine the values of the parameters α_{1:n}, ω_{1:n}, and ζ_{1:n} that minimize the difference between the measurement function M(ω) and the resonance mixture model G(ω; α_{1:n}, ω_{1:n}, ζ_{1:n}) when the number of clusters is n, as expressed by Equation 5 above.

For example, the electronic device 101 may determine the values of the parameters of the resonance mixture model by exploring (testing) values of parameters through an optimization technique such as gradient descent or Gauss-Newton.

The example of calculating the loss according to Equation 5 above is one of the various examples. The loss between the measurement function M(ω) (or the spectrum 130) and the resonance mixture model G(ω; α_{1:n}, ω_{1:n}, ζ_{1:n}) (when the number of clusters is n) may be calculated using a technique that is different from the example describe above.

The electronic device 101 may calculate the values of the parameters for each number of clusters. For example, when the set maximum number of clusters is 3, the electronic device 101 may calculate the plurality of parameters of the resonance mixture model when the number of clusters is one, two, and three, respectively.

In operation 440, the electronic device 101 may generate a model 140 corresponding to the spectrum 130 based on the loss and the determined values of the respective parameters. For example, the electronic device 101 may determine values of the parameters of the resonance mixture model for each number of clusters. The electronic device 101 may determine that a resonance mixture model has the smallest loss between the resonance mixture model and the spectrum 130, and may use that modes as the model 140 corresponding to the spectrum 130 (among the resonance mixture models calculated for each number of clusters).

The electronic device 101 may determine the model 140 corresponding to the spectrum 130 based on a model likelihood (or loss) and the number of clusters.

$$Score = - 2 * log ( L ) + k * n , \qquad Equation 6$$

$$k = \{ \begin{matrix}2 , & ( for AIC ) \\ log , & ( for BIC )\end{matrix}$$

Equation 6 is for computing a score (Score) according to the loss L and the number of clusters n. In Equation 6 above, as the number of clusters increases, the score may correspondingly increase. The electronic device 101 may determine the optimal number of clusters according to Equation 6 above. The electronic device 101 may determine that the number of clusters n when the score (which is calculated according to the number of clusters and the loss) is the smallest is the optimal number of clusters.

The electronic device 101 may determine that the resonance mixture model (according to the number of clusters) when the score is the smallest is the model 140 to be used as corresponding to the spectrum 130.

In operation 450, the electronic device 101 may generate, based on set noise information, a denoising model in which noise information is removed from the model 140. For example, the spectrum 130 measured from an element (or compound, molecule, etc.) may include energy emitted from a dopant and energy emitted from a material other than a dopant. That is to say, some portions of the spectrum 130 may have a component attributable to material other than the target element/compound/molecule. For example, the noise information may include information about the spectrum of energy emitted from the material other than a dopant. The noise information may include information about the spectrum of energy emitted from the material other than a dopant, such as, frequency, amplitude, and intensity.

The electronic device 101 may generate the denoising model by removing the noise information from the model 140. In order to analyze the characteristics of an element/compound/molecule, information about the spectrum of energy emitted from a dopant, such as, peak and area, may be analyzed. By removing the spectrum of energy emitted from the material (e.g., host) other than a dopant, the electronic device 101 may model the spectrum emitted from a dopant with high accuracy.

In operation 460, the electronic device 101 may generate separate models from the model 140 based on the determined values of parameters.

For example, the electronic device 101 may perform spectrum separation based on the values of the parameters.

A conventional Gaussian mixture model (GMM) may model a spectrum based on a Gaussian function. A spectrum emitted from an element/compound/molecule may have a downward-broadening, left-right asymmetric shape. When a spectrum is modeled using a GMM technique, a significant error may occur because of the difference between the shape of the spectrum and the shape of the Gaussian function. This may require a large number of Gaussian functions.

The electronic device 101 may improve modeling accuracy and reduce errors by modeling the spectrum 130 using the resonance mixture model based on the resonance function.

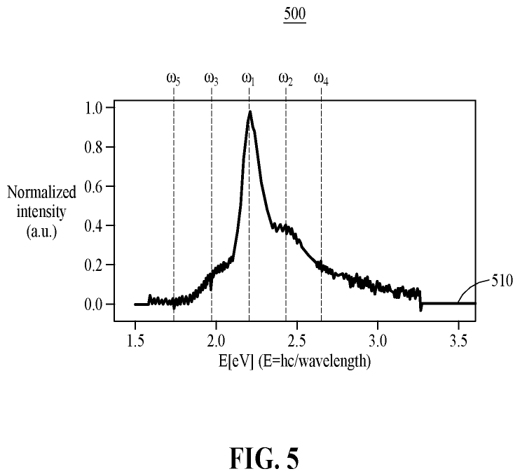

FIG. 5 illustrates an example of operations of determining initial values of a plurality of parameters of a resonance mixture model by the electronic device 101, according to one or more embodiments.

As illustrated in FIG. 5, a spectrum 510 may have a left-right asymmetrical shape that peaks at the angular frequency ω₁. Also, the spectrum 510 may have a downward-broadening shape.

For example, as expressed by Equation 4 above, the electronic device 101 may determine the initial value ωₙ(n=1, 2, 3, 4, 5) of the angular frequency among parameters corresponding to the spectrum 510.

The electronic device 101 may determine the initial values of the weight αₙ and the damping ratio ζₙ. The electronic device 101 may determine the values of the parameters using the initial values of the determined values of the parameters, as expressed by Equation 5 above.

The electronic device 101 may determine the values of the parameters of the resonance mixture model according to the number of clusters within the set maximum number of clusters.

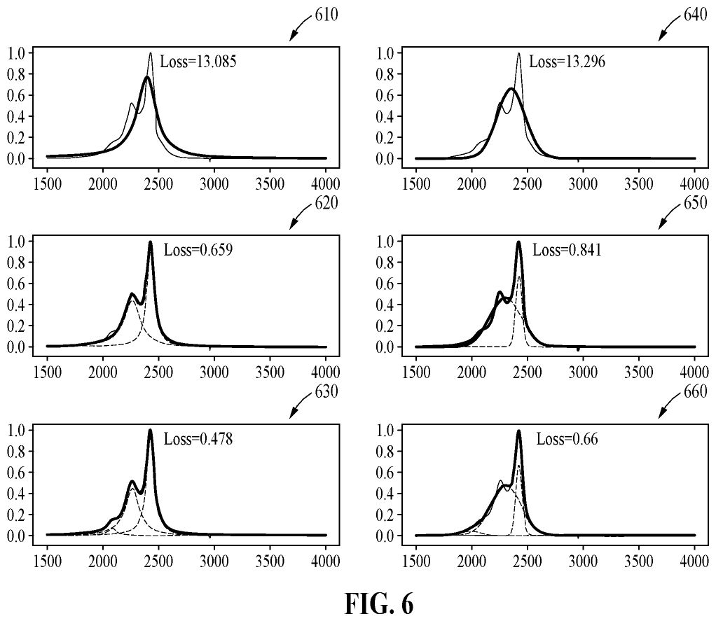

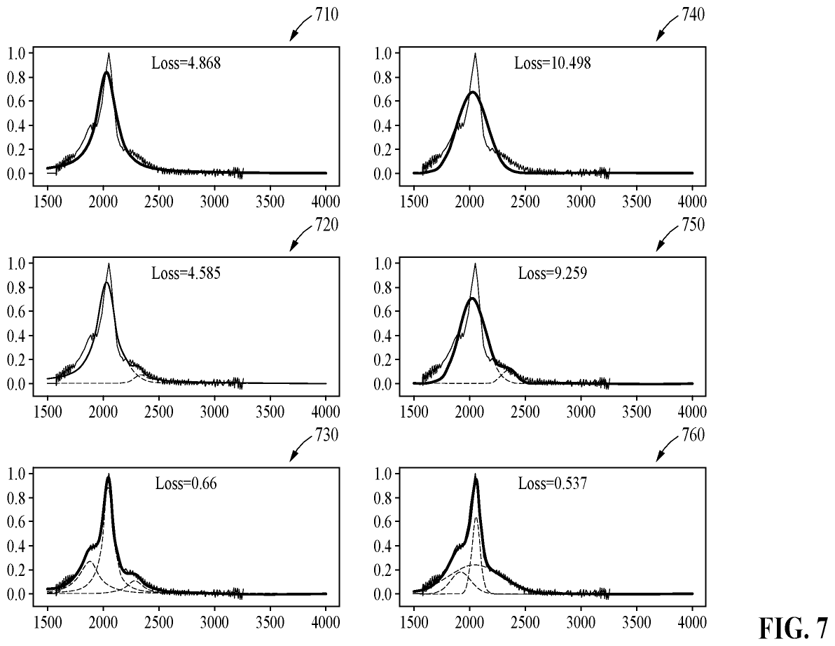

FIGS. 6 and 7 illustrate an example of a model of a spectrum, according to one or more embodiments.

Referring to FIG. 6, a graph 610 depicts a spectrum modeled using a resonance mixture model when the number of clusters is one. A graph 620 depicts the spectrum modeled using the resonance mixture model when the number of clusters is two. And a graph 630 depicts the spectrum modeled using the resonance mixture model when the number of clusters is three.

Still referring to FIG. 6, a graph 640 depicts the spectrum modeled according to a GMM when the number of clusters is one. A graph 650 depicts the spectrum modeled according to the GMM when the number of clusters is two. And a graph 660 depicts the spectrum modeled according to the GMM when the number of clusters is three.

Referring to FIG. 6, the spectrum may be a clean spectrum without noise.

Referring to FIG. 7, a graph 710 depicts a spectrum modeled using the resonance mixture model when the number of clusters is one. A graph 720 depicts the spectrum modeled using the resonance mixture model when the number of clusters is two. And a graph 730 depicts the spectrum modeled using the resonance mixture model when the number of clusters is three.

Still referring to FIG. 7, a graph 740 depicts the spectrum modeled according to the GMM when the number of clusters is one. A graph 750 depicts the spectrum modeled according to the GMM when the number of clusters is two. And a graph 760 depicts the spectrum modeled according to the GMM when the number of clusters is three.

Referring to FIG. 7, the spectrum may be a noisy spectrum.

Referring to FIGS. 6 and 7, the electronic device 101 may determine the values of the parameters of the resonance mixture model for each number of clusters. The electronic device 101 may generate resonance mixture models corresponding to the spectrum, such as the graphs 610, 620, 630, 710, 720, and 730. The electronic device 101 may determine a model corresponding to the spectrum based on a loss and the number of clusters among the resonance mixture models corresponding to the spectrum.

For example, referring to FIG. 6, the loss between the resonance mixture model and the spectrum is the smallest when the number of clusters is three, and thus, the electronic device 101 may determine that the resonance mixture model to be used/selected as corresponding to the spectrum is the model when the number of clusters is three.

For example, referring to FIG. 7, the loss between the resonance mixture model and the spectrum is the smallest when the number of clusters is three, and thus, the electronic device 101 may determine that the resonance mixture model to be used/selected as corresponding to the spectrum is the model when the number of clusters is three.

Referring to FIGS. 6 and 7, the loss of the resonance mixture model determined by the electronic device 101 is less than the loss of the model determined according to the GMM.

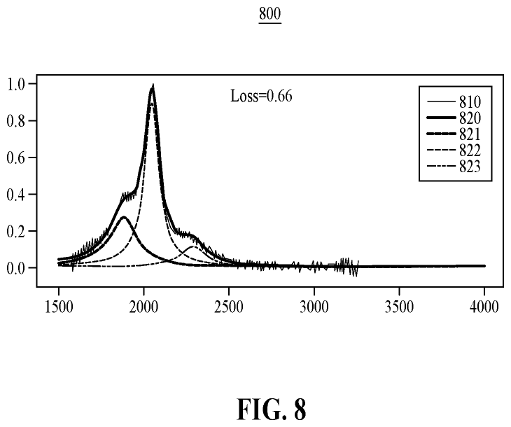

FIG. 8 illustrates an example of separate models 821, 822, and 823 of a model 820 that models a spectrum 810, according to one or more embodiments. Although difficult to discern, the line of the spectrum 810 in FIG. 8 closely follows the line of the model 820.

The graph 800 of FIG. 8 may be the graph 730 of FIG. 7.

Referring to FIG. 8, the electronic device 101 may determine the model 820 that is to be used as corresponding to the spectrum 810 by using a resonance mixture model. The electronic device 101 may generate the separate models 821, 822, and 823 from the model 820. For example, the electronic device 101 may generate the separate models 821, 822, and 823 based on determined parameters.

For example, referring to FIG. 8, when the model 820 is the resonance mixture model G(ω; α_{1:n}, ω_{1:n}, ζ_{1:n})=α₁G₁(ω; ω₁, ζ₁)+a₂G₂(ω; ω₂, ζ₂)+a₃G₃ (ω; ω₃, ζ₃), the electronic device 101 may determine that the separate model 821, the separate model 822, and the separate model 823 are α₃G₃ (ω; ω₃, ζ₃), α₁G₁ (ω; ω₁, ζ₁), and α₂G₂ (ω; ω₂, ζ₂), respectively.

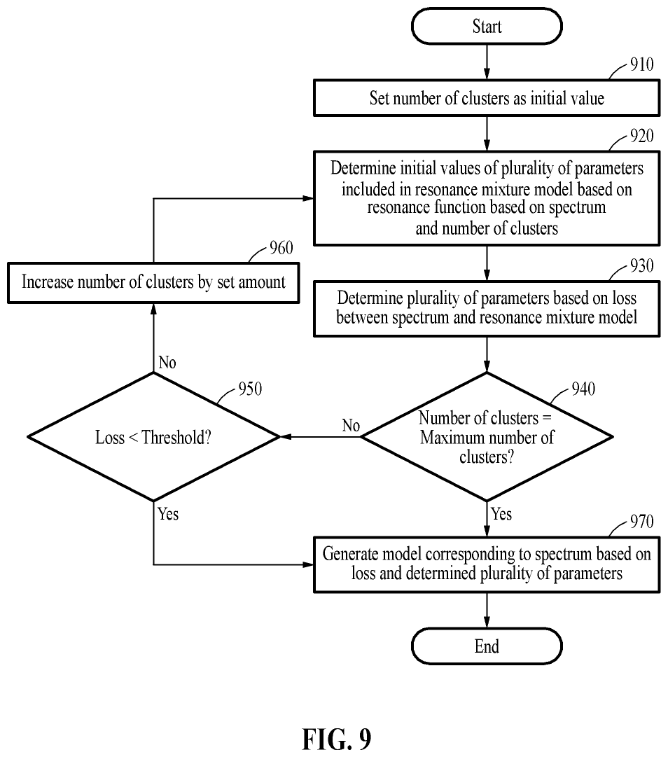

FIG. 9 illustrates an example of operations of a method of modeling a spectrum, according to one or more embodiments.

It may be understood that operations 910 to 970 are performed by the processor 120 of the electronic device 101.

In operation 910, the electronic device 101 may set the number of clusters as an initial value (e.g., 1).

In operation 920, the electronic device 101 may determine, based on a spectrum and the number of clusters, initial values of a plurality of parameters included in a resonance mixture model based on a resonance function. For example, the electronic device 101 may determine the initial values of the parameters according to Equation 4 above.

In operation 930, the electronic device 101 may determine values of the parameters based on the loss between the spectrum and the resonance mixture model. For example, the electronic device 101 may determine (e.g., test/search for) the values of the parameters to minimize the loss, as expressed by Equation 5 above.

In operation 940, the electronic device 101 may determine whether the number of clusters is the set maximum number of clusters.

In operation 940, when the number of clusters is not the set maximum number of clusters, the electronic device 101 may proceed to operation 950 and determine whether the loss is less than a set threshold value.

When it is determined in operation 950 that the loss is greater than or equal to the set threshold value, the electronic device 101 may increase the number of clusters by a set amount (e.g., 1, but possibly more) in operation 960.

The electronic device 101 may repeatedly perform operations 920, 930, 940, 950, and 960 according to the number of clusters increased by the set amount.

In operation 940, when the number of clusters is the set maximum number of clusters, the electronic device 101 may, in operation 970, generate a model corresponding to a spectrum based on the loss and the determined values of the parameters. For example, the electronic device 101 may determine that a resonance mixture model with a minimum loss is the model to be selected as corresponding to the spectrum.

For example, the electronic device 101 may determine the model corresponding to the spectrum based on the loss and the number of clusters that minimize the score of Equation 6 above.

In addition, even before the maximum number of clusters is reached, if in operation 950 it is determined that the loss is less than the set threshold value, then the electronic device 101 may proceed to operation 970 and generate the model corresponding to the spectrum based on the loss and the determined values of the parameters.

As noted, in operation 950 the electronic device 101 may determine whether the loss is greater than or equal to the set threshold value. For example, when there is a large number of clusters, it may not be possible to determine values of parameters of the resonance mixture model corresponding to the spectrum. When it is not possible to determine the values of the parameters, the loss between the resonance mixture model and the spectrum may increase. When it is not possible to determine the values of the parameters, the loss may be greater than or equal to the set threshold value.

For example, when the loss is greater than or equal to the set threshold value, the electronic device 101 may increase the number of clusters according to operation 960 and stop repeating operation 920, operation 930, operation 940, and operation 950.

For example, when the loss is greater than or equal to the set threshold value, the electronic device 101 may generate the model corresponding to the spectrum according to operation 970.

The computing apparatuses, the models, the electronic devices, the processors, the memories, the displays, the information output system and hardware, the storage devices, and other apparatuses, devices, units, modules, and components described herein with respect to FIGS. 1-9 are implemented by or representative of hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-9 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. An electronic device comprising:
one or more processors; and
a memory electrically connected to the processor and storing instructions configured to cause the one or more processors to:
determine, based on a spectrum and a number of clusters, initial values of respective parameters comprised in a resonance mixture model that models a resonance function;
determine, for each of the number of clusters, values of the parameters based on a loss between the spectrum and the resonance mixture model; and
generate a model corresponding to the spectrum based on the determined values of the parameters.

2. The electronic device of claim 1, wherein the instructions are further configured to cause the one or more processors to determine an optimal number of clusters based on the number of clusters and the loss.

3. The electronic device of claim 1, wherein the instructions are further configured to cause the one or more processors to generate, based on set noise information, a denoised model in which noise information is removed from the generated model.

4. The electronic device of claim 1, wherein the instructions are further configured to cause the one or more processors to generate separate models from the model based on the determined values of the parameters.

5. The electronic device of claim 1, wherein the instructions are further configured to cause the one or more processors to set the initial values of the parameters for each of the number of clusters within a set maximum number of clusters.

6. The electronic device of claim 1, wherein the instructions are further configured to cause the one or more processors to select, as the values of the parameters for the model, from among the determined values, values that correspond to when the loss is within a set range.

7. An electronic device comprising:
one or more processors; and
a memory electrically connected to the one or more processors and configured to cause the one or more processors to:
sample a spectrum comprising measures of frequency or wavelength sub-bands;
for a number of molecule clusters, determine, based on the spectrum, respective sets of initial values of parameters comprised in resonance mixture models that model a resonance function;
determine, for each of the number of molecule clusters, according to the initial values and the resonance mixture models, optimal values of the parameters that minimize a loss between the sampling of the spectrum and the resonance mixture models; and
generate, based on the determined optimal values of the parameters, a model corresponding to the spectrum among the resonance mixture models.

8. The electronic device of claim 7, wherein the instructions are further configured to cause the one or more processors to determine an optimal number of clusters based on the number of clusters and the loss.

9. The electronic device of claim 8, wherein the instructions are further configured to cause the one or more processors to generate, based on set noise information, a denoised model in which noise information is removed from the generated model.

10. The electronic device of claim 8, wherein the instructions are further configured to cause the one or more processors to generate separate models from the model based on the determined optimal values.

11. A method of modeling a spectrum, the method performed by a computing device and comprising:
for a number of molecule clusters, determining, based on a spectrum, respective initial values of a plurality of parameters comprised in a resonance mixture model that models a resonance function;
determining values of the parameters based on a loss between the spectrum and values produced by the resonance mixture model for each of the number of clusters; and
generating a model corresponding to the spectrum based on the determined values of the parameters.

12. The method of claim 11, wherein the generating of the model comprises determining an optimal number of molecule clusters based on the number of molecule clusters and the loss.

13. The method of claim 11, further comprising:
generating, based on set noise information, a denoised model in which noise information is removed from the model.

14. The method of claim 11, further comprising:
generating separate models from the model based on the determined values of the parameters.

15. The method of claim 11, wherein the determining of the initial values of the parameters comprises setting the initial values for each of the number of molecule clusters within a set maximum number of clusters.

16. The method of claim 11, wherein the generating of the model comprises selecting the resonance mixture model as the model when the loss is within a set range.

17. The method of claim 11, wherein the resonance mixture model models two or more resonant motion modes of atoms in a molecule, the two or more resonant motion modes comprising two or more of: a symmetric stretch mode, an asymmetric stretch mode, a bending mode, or a rocking mode.

18. The method of claim 11, wherein the values are determined for the model using an optimization algorithm that iteratively finds the values that minimize loss between the spectrum and the values produced by the resonance mixture model.
